(19) United States
(12) Patent Application Publication
(10) Pub. No.: US 2005/0236181 A1
(43) Pub. Date: Oct. 27, 2005

(54) Novel ECP method for preventing the formation of voids and contamination in vias

(75) Inventors: Kei-Wei Chen, Taipei (TW); Shih-Ho Lin, Hsin-Chu (TW); Chun-Chang Chen, Hsin-Chu (TW); Ching-Hwan Su, Hsin-Chu (TW); Yu-Ku Lin, Hsin-chu city (TW); Ying-Lang Wang, Taichung County (TW); De-Dui Marvin Liao, Tainan (TW); Meng-Chao Tzeng, Hsinchu (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co., Ltd.

(21) Appl. No.: 10/917,543

(22) Filed: Aug. 12, 2004

Related U.S. Application Data
(60) Provisional application No. 60/565,111, filed on Apr. 24, 2004.

(51) Int. Cl. H05K 1/03; H05K 1/09; H05K 1/11

(52) U.S. Cl. 174/256; 174/262; 29/852

(57) ABSTRACT

A method for preventing the formation of voids and contaminants in vias during the fabrication of a metal interconnect structure such as a dual damascene structure is disclosed. The method includes providing a substrate; providing a dielectric layer having trench openings and via openings on the substrate, wherein the ratio of the sum of the areas of the trench openings to the sum of the areas of the via openings is between 1 and 300; wherein the via opening bottom has a width of less than about 25 μm; and electroplating a metal in the trench openings and via openings. An interconnect structure having at least one void-free via is further disclosed.

This application claims the benefit of U.S. Provisional Application No. 60/565,111, filed on Apr. 24, 2004.

### FIELD OF THE INVENTION

The present invention relates to electrochemical plating processes used to form metal interconnects in vias and trenches in the semiconductor industry. More particularly, the present invention relates to a novel method for preventing the presence of voids and contamination in metal interconnects filling via openings by controlling the trench/via area density ratio, the accelerator/suppressor ratio, the plating current density and the width of vias in an electrochemical plating (ECP) process.

### BACKGROUND OF THE INVENTION

In the fabrication of semiconductor integrated circuits, metal conductor lines are used to interconnect the multiple components in device circuits on a semiconductor wafer. A general process used in the deposition of metal conductor line patterns on semiconductor wafers includes deposition of a conducting layer on the silicon wafer substrate; formation of a photoresist or other mask such as titanium oxide or silicon oxide, in the form of the desired metal conductor line pattern, using standard lithographic techniques; subjecting the wafer substrate to a dry etching process to remove the conducting layer from the areas not covered by the mask, thereby leaving the metal layer in the form of the masked conductor line pattern; and removing the mask layer typically using reactive plasma and chlorine gas, thereby exposing the top surface of the metal conductor lines. Typically, multiple alternating layers of electrically conductive and insulative materials are sequentially deposited on the wafer substrate, and conductive layers at different levels on the wafer may be electrically connected to each other by etching vias, or openings, in the insulative layers and filling the vias using aluminum, tungsten or other metal to establish electrical connection between the conductive layers.

Deposition of conductive layers on the wafer substrate can be carried out using any of a variety of techniques. These include oxidation, LPCVD (low-pressure chemical vapor deposition), APCVD (atmospheric-pressure chemical vapor deposition), and PECVD (plasma-enhanced chemical vapor deposition). In general, chemical vapor deposition involves reacting vapor-phase chemicals that contain the required deposition constituents with each other to form a nonvolatile film on the wafer substrate. Chemical vapor deposition is the most widely-used method of depositing films on wafer substrates in the fabrication of integrated circuits on the substrates.

Due to the ever-decreasing size of semiconductor components and the ever-increasing density of integrated circuits on a wafer, the complexity of interconnecting the components in the circuits requires that the fabrication processes used to define the metal conductor line interconnect patterns be subjected to precise dimensional control. Advances in lithography and masking techniques and dry etching processes, such as RIE (Reactive Ion Etching) and other plasma etching processes, allow production of conducting patterns with widths and spacings in the submicron range. Electrode position or electroplating of metals on wafer substrates has recently been identified as a promising technique for depositing conductive layers on the substrates in the manufacture of integrated circuits and flat panel displays. Such electrodeposition processes have been used to achieve deposition of the copper or other metal layer with a smooth, level or uniform top surface. Consequently, much effort is currently focused on the design of electroplating hardware and chemistry to achieve high-quality films or layers which are uniform across the entire surface of the substrates and which are capable of filling or conforming to very small device features. Copper has been found to be particularly advantageous as an electroplating metal. Therefore, in the semiconductor industry, copper is being increasingly used as the interconnect material for microchip fabrication.

The conventional method of depositing a metal conducting layer and then etching the layer in the pattern of the desired metal line interconnects and vias cannot be used with copper because copper is not suitable for dry-etching. Special considerations must also be undertaken in order to prevent diffusion of copper into silicon during processing. Therefore, the dual-damascene process has been developed and is widely used to form copper metal line interconnects and vias in semiconductor technology. In the dual-damascene process, the dielectric layer rather than the metal layer is etched to form trenches and vias, after which the copper is electroplated into the trenches and vias to form the desired interconnects. Finally, the electroplated copper is subjected to chemical mechanical planarization (CMP) to remove excess copper (copper overburden) extending from the trenches.

While there exist many variations of a dual-damascene process flow, the process typically begins with deposition of a silicon dioxide dielectric layer of desired thickness which corresponds to the thickness for the via or vias to be etched in the dielectric layer. Next, a thin etch stop layer, typically silicon nitride, is deposited on the dielectric layer. Photolithography is then used to pattern via openings over the etch stop layer, after which dry etching is used to etch via openings in the etch stop layer. The patterned photoresist is then stripped from the etch stop layer after completion of the etch. A remaining dielectric layer the thickness of which corresponds to the thickness of the trench for the metal interconnect lines is then deposited on the etch stop layer, and photolithography followed by dry etching is used to pattern the trenches in the remaining dielectric layer and the vias beneath the trenches. The trench etching stops at the etch stop layer, while the vias are etched in the first dielectric layer through the openings in the etch stop layer and beneath the trenches. Next, a barrier material of Ta or TaN is deposited on the sidewalls and bottoms of the trenches and vias using ionized PVD. A uniform copper seed layer is then deposited on the barrier layer using CVD. After the trenches and vias are electroplated with copper, the copper overburden extending from the trenches is removed and the upper surfaces of the metal lines planarized using CMP. In the dual damascene process described above, the vias and trenches are etched in the same step, and the etch stop layer defines the bottom of the trenches. In other variations, the trench is patterned and etched after the via.

A typical standard or conventional electroplating system for depositing a metal such as copper onto a semiconductor wafer includes a standard electroplating chamber having an adjustable current source, a bath container which holds an electrolyte electroplating bath solution (typically acid copper sulfate solution), and a copper anode and a cathode immersed in the electrolyte solution. Semiconductor wafer which is to be electroplated with metal is connected to the cathode. Both the anode and the semiconductor wafer/cathode are connected to the current source by means of suitable wiring. The electroplating bath solution may include an additive for filling of submicron features and leveling the surface of the copper electroplated on the wafer. An electrolyte holding tank may further be connected to the bath container for the addition of extra electrolyte solution to the bath container, as needed.

In operation of the electroplating system, the current source applies a selected voltage potential typically at room temperature between the anode and the cathode/wafer. This potential creates a magnetic field around the anode and the cathode/wafer, which magnetic field affects the distribution of the copper ions in the bath. In a typical copper electroplating application, a voltage potential of about 2 volts may be applied for about 2 minutes, and a current of about 4.5 amps flows between the anode and the cathode/wafer. Consequently, copper is oxidized at the anode as electrons flow out from the copper anode and the ionic copper in the copper sulfate solution bath is reduced to form a copper electroplate at the interface between the cathode/wafer and the copper sulfate bath.

The copper oxidation reaction which takes place at the anode is illustrated by the following reaction equation:
Cu - - - >Cu⁺⁺+2e⁻

The oxidized copper cation reaction product forms ionic copper sulfate in solution with the sulfate anion in the bath 20:
Cu⁺⁺+SO₄⁻⁻ - - - >Cu⁺⁺SO₄⁻⁻

At the cathode/wafer, the electrons harvested from the anode flowed through the wiring reduce copper cations in the copper sulfate solution bath to electroplate the reduced copper onto the cathode/wafer:
Cu⁺⁺+2e⁻ - - - >Cu

After the copper is electroplated onto the wafer, the wafer is frequently subjected to a CMP (chemical mechanical polishing) process to remove excess copper (copper overburden) from the electroplated copper layer and smooth the surface of the layer. In an ECP process, an acidic copper electroplating bath solution typically includes various additives such as suppressors, accelerators and levelers. In order to meet increasingly severe gap fill requirements, the additive concentrations are selected to achieve rapid bottom-up fill optimization in high aspect ratio vias and trenches, as well as microscopic and macroscopic uniformity.

Electroplating of interconnects having high structural and functional integrity in vias is highly dependent on a complex interplay between such factors as the trench/via pattern density or area ratio, the accelerator/suppressor concentration ratio, the plating current density and the ratio of the width of the via top to the width of the via bottom. According to the present invention, the formation of contamination and voids in vias of metal interconnect structures can be reduced or eliminated by controlling such factors as the trench/via pattern density ratio, the ratio of A/S (Accelerator/Suppressor) concentration in the electroplating bath solution, the electroplating current density, the via bottom width, and the ratio of trench top width to via bottom width during fabrication of the structures.

### SUMMARY OF THE INVENTION

The present invention is generally directed to a method for preventing the formation of voids and contaminants in vias during the fabrication of a metal interconnect structure such as a dual damascene structure. The method includes providing a substrate; providing a dielectric layer having trench openings and via openings on the substrate, wherein the ratio of the sum of the areas of the trench openings to the sum of the areas of the via openings is between 1 and 300, and preferably, between 1 and 100; wherein the via opening bottom has a width of less than about 25 μm; and electroplating a metal in the trench openings and via openings. The ratio of A/S (Accelerator/Suppressor) concentration in the electroplating bath solution used to form interconnects in via openings is preferably less than about 10 and greater than about 3. The electroplating current density is preferably less than about 20 mA/cm².

The present invention further includes an interconnect structure having at least one void-free via. The structure includes a substrate, a low-k dielectric layer provided on the substrate, and trenches and vias provided in the dielectric layer. The trenches and vias have a trench/via pattern density or area ratio of less than typically about 300 or a trench/via width ratio of typically between about 1 and 20.

### BRIEF DESCRIPTION OF THE DRAWINGS

The invention will now be described, byway of example, with reference to the accompanying drawings, in which:

FIG. 1 is a schematic of a trench and underlying via, illustrating the formation of voids in the via during a gap-filling process when a superfilling index (P) is less than 0 and formation of voids in the bulk electroplating solution when P is greater than 0;

FIG. 2 is a graph which indicates the relationship between the superfilling index and the ratio of accelerator and suppressor concentration in an electroplating solution;

FIGS. 3(A) and 3(B) are cross-sectional views illustrating a dense type and an iso-type trench openings, respectively;

FIG. 4 is a graph which illustrates the relationship between the accelerator/suppressor (A/S) concentration ratio and the superfilling index (P);

FIG. 5 is a cross-sectional view of a dual-damascene interconnect structure fabricated according to the present invention;

FIG. 6 is a top view of a section of a dual-damascene interconnect structure fabricated according to the present invention; and

FIG. 7 is a cross-sectional of a dual damascene interconnect structure fabricated according to the present invention, illustrating a preferred ratio of trench top width to via bottom width in an interconnect structure fabricated according to the present invention.

### DETAILED DESCRIPTION OF THE INVENTION

The present invention generally contemplates a method which prevents the formation of voids and contaminants in vias during the fabrication of a metal interconnect structure such as a dual damascene structure in a dielectric layer. According to the method, a dielectric layer is provided on a substrate and trench openings and via openings are provided in the dielectric layer. The trench/via pattern density ratio is typically between about 1 and about 300. Preferably, the trench/via pattern density ratio is between about 1 and about 100. The via opening bottom preferably has a width of less than typically about 25 μm. A metal, preferably copper, is electroplated in the trench openings and via openings to form the trench metal line and via interconnects. The ratio of A/S (Accelerator/Suppressor) concentration in the electroplating bath solution used to form the via interconnects in the via openings is preferably less than about 10 and greater than about 3. The electroplating current density is preferably less than typically about 20 mA/cm².

The present invention further contemplates an interconnect structure having at least one via which is substantially free of voids. The interconnect structure includes a substrate, a low-k dielectric layer provided on the substrate, and trenches and vias provided in the dielectric layer. In one embodiment, the trenches and vias have a trench/via pattern density or area ratio of less than typically about 300, and preferably, less than typically about 100. In another embodiment, the trenches and vias have a trench/via width ratio of typically between about 1 and 20.

In a trench/via pattern density ratio determination, the sum of the areas (width×length) of all trenches in a dual damascene metal interconnect structure and the sum of the areas (area size by vertical view) of all vias in the structure are calculated. Thus, the lower the trench/via pattern density ratio, the higher the density of vias in the structure and the lower the number of widely separated vias in the structure. It has been found that interconnect structures exhibit an increasingly high WAT (wafer acceptance test) failure rate as the trench/via pattern density ratio exceeds about 100. This is due, at least in part, to the fact that widely separated vias are more likely than dense vias to become contaminated with sulfur residues during the electroplating process.

In the electroplating process, there exists various sources of sulfur residues that can potentially contaminate vias in an interconnect structure. For example, the electroplating solution is typically copper sulfate. Accelerator and leveler additives to the electroplating solution typically contain silicon. Other sources of silicon include the electroplating environment, photoresist residues remaining on the wafer, and surfactants.

In interconnect structures having a high via pattern density, the electroplating bath solution forms a thinner boundary layer adjacent to the structure than is the case with regard to structures having widely separated vias. This results in a more uniform distribution of accelerator molecules and electric field among the vias. In contrast, the thicker boundary layer which characterizes structures having widely separated vias results in a higher accelerator concentration and electric field, resulting in a partial polarity in the bottom of the via which causes voids and attracts sulfur residues.

Compared with the gapfill deposition rate at different areas, a superfilling index (P) can be defined by the equation:
P=(R_{bottom}−Rₜₒₚ)/Rₜₒₚ*100%

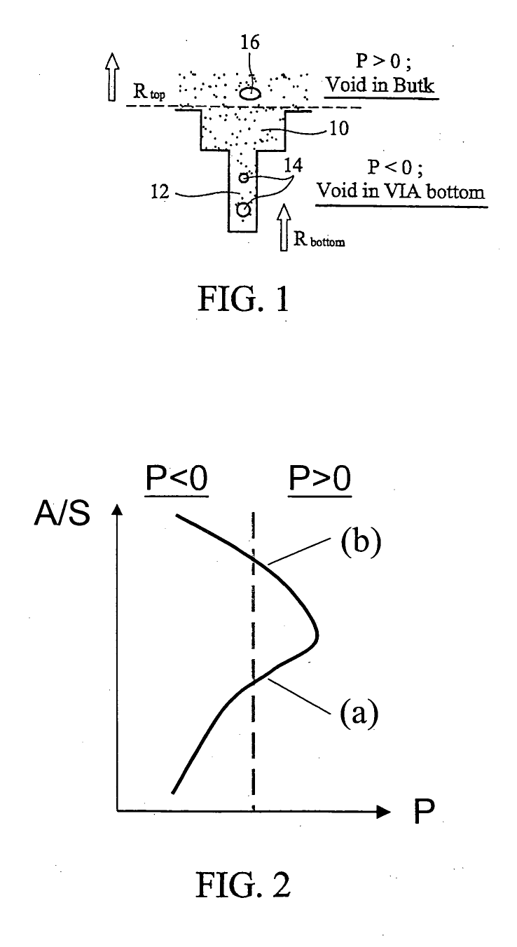

Superfilling herein is a term referring to a deposition phenomenon that produces void-free and seamless deposits inside trenches or vias with vertical walls and high aspect ratios. Referring to FIG. 1, Rₜₒₚ refers to the gapfill deposition rate on the bulk surface outside a trench 10, whereas R_{bottom} refers to the gapfill deposition rate inside the trench 10 and an underlying via 12 therein. When P<0, indicating a depositing phenomenon wherein deposition is faster on the surface outside trench 10 rather than that inside the trench 10 and via 12, voids 14 tend to form inside the via since faster deposition on the surface outside trench 10 tends to merge and close the top of trench 10 before whole trench 10 and via 12 are completely deposited; when P>0, indicating a depositing phenomenon wherein deposition is slower on the surface outside trench 10 rather than that inside the trench 10 and via 12, the deposition can completely fill the trench 10 and via 12 and it results in a substantially void free deposition in the trench 10 and via 12. Therefore, a superfilling index (P) larger than zero is preferred for optimum electroplating.

The A/S ratio (the accelerator concentration in the electroplating solution over the suppressor concentration in the solution) is to be discussed before referring to the graph of FIG. 2. Accelerators are organic compounds that enhance the nucleation of metal like Cu on the surface to be deposited, thus increase the deposition rate on surface. To the contrary, suppressors are organic polymers that passivate the surface thereby block the surface from reacting with the solution for nucleation, result in lower deposition rate on surface. Since accelerators, usually smaller molecules, tend to distribute in small cavities such as trenches and vias, while suppressors, usually larger molecules, tend to distribute less in cavities but instead on flat and spacious surface. Thus, the addition of both accelerators and suppressors achieves an improved electroplating process, i.e, superfilling. At different A/S ratios, the electroplating process can thus be optimized to different degrees.

In FIG. 2, a relationship between the A/S ratio and the superfilling index P is plotted. At the beginning, as A/S ratio increases, shown by the lower portion of the curve marked as (a), the index P increases and gradually moves form zone P<0 into zone P>0, indicates an optimized electroplating process is achieved by increasing the A/S ratio. However, after a peak value of index P, the increasing A/S ratio reverses to decrease with index P, shown by the upper portion of the curve marked as (b). The peak value of index P indicates when the surface of sidewall of trenches or vias is fully covered by accelerators and each accelerator molecule nucleates without repelling disturbing others achieving a saturation condition with accelerators. After the peak value, the excess accelerators, which are organic compounds, become the origins of impurities and contaminants and thereby hinder the following deposition onto the nucleated surface, resulting in a slow down in the deposition rate inside the trenches or vias. This is why increasing A/S ratios decrease the index P after the peak value.

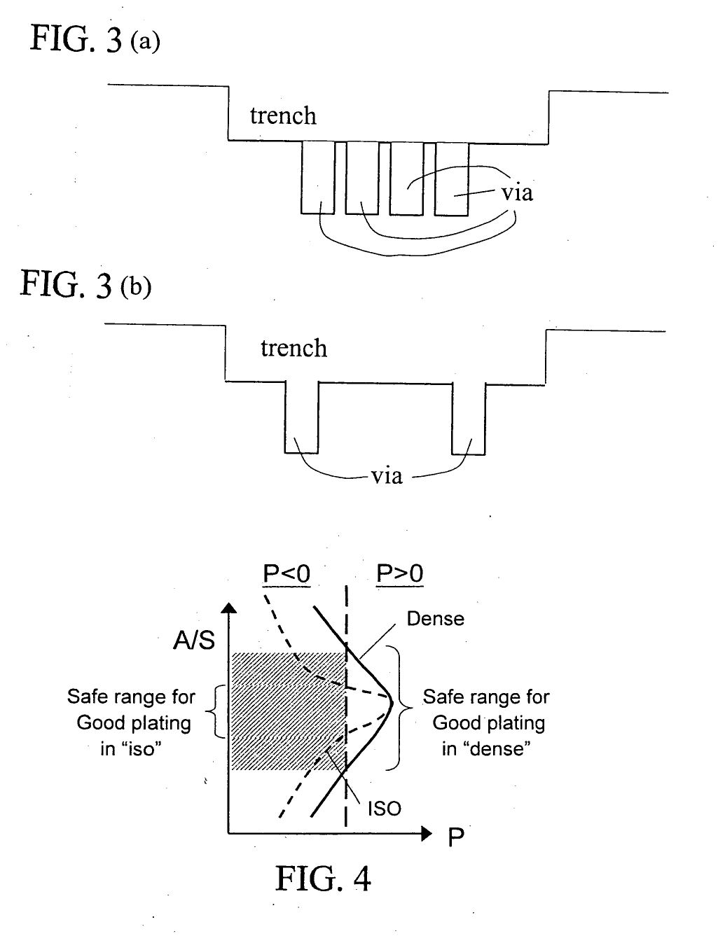

To further illustrate the relationship between the A/S ratio and the superfilling index P, two patterns with different trench/via area densities are shown in FIG. 3. FIG. 3(A) represents a situation where more via openings are formed inside a trench opening, commonly known as a “dense” type. To the contrary, a situation where only few widely-separated via openings are formed inside a trench opening, i.e., FIG. 3(B), is known as an “iso” type. FIG. 4 illustrates the relationship between the accelerator/suppressor (A/S) concentration ratio and the superfilling index (P) in two situations shown in FIGS. 3(A) and 3(B). In FIG. 4, the left zone of the graph, which corresponds to P<0, represents a superfilling index which is not optimum for electroplating and the right zone of the graph corresponds to P>0, which is optimum for electroplating. For optimized electroplating, the region wherein index P>0 is considered as a safe area, and the corresponding A/S ratio range is a safe range for the process. Usually, the safe A/S ratio range of dense trench/via density shown in FIG. 3(A) is wider than that of the situation shown in FIG. 3(B). This is because dense trench/via density of FIG. 3(A), with more via openings inside the trench opening, can accept more accelerators before saturation occurs.

The shaded region in FIG. 4 defines a safe range for electroplating conditions, in which contamination-free and void-free interconnect structures can be fabricated in the vias. By fabricating metal interconnect structures such as dual damascene structures according to a set of parameters, in accordance with the present invention, vias which are substantially devoid of contamination or voids can be formed in via openings. According to one parameter, the metal trench/via pattern density ratio is less than typically about 300, and preferably, less than typically about 100. According to another parameter, the ratio of A/S (Accelerator/Suppressor) concentration in the electroplating bath solution is less than typically about 10. According to another parameter, the electroplating current density is less than typically about 20 mA/cm². According to still another parameter, the ratio of the width of the trench top to the via bottom is about 1˜20.

The methodology provided by the present invention enables the achievement of a significant improvement in reducing void and contamination formations in situations where the via bottom has a width of less than typically about 0.25 μm. For future generation semiconductor devices with smaller via bottom widths, i.e., less than 0.2 μm or 0.10 μm, the formation of void and contamination in the vias may become more severe when devices are fabricated by conventional deposition methods.

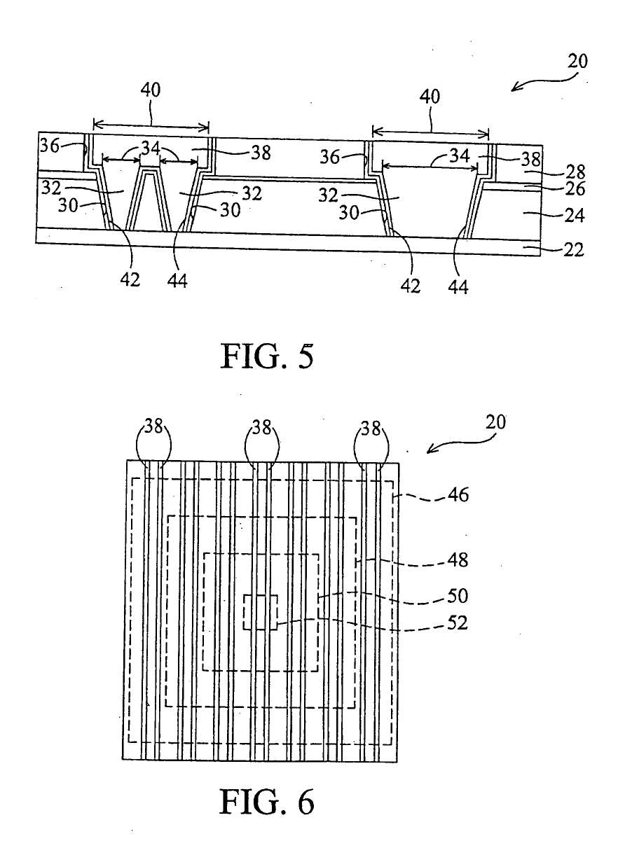

Referring now to FIGS. 5-7 wherein a dual damascene metal interconnect structure 20 fabricated according to the present invention method is shown. The structure 20 includes a substrate 22 on which is provided a lower dielectric layer 24. An etch stop layer 26 and an upper dielectric layer 28 are typically sequentially deposited on the lower dielectric layer 24. The lower dielectric layer 24 and upper dielectric layer 28 are preferably a low-k dielectric film and may be Black Diamond®, Blok®, Silk®, Coral® DEMS, or FSG, for example. The lower dielectric layer 24 and upper dielectric layer 28 preferably have a dielectric constant (k) of <3.9 or preferably <3.0.

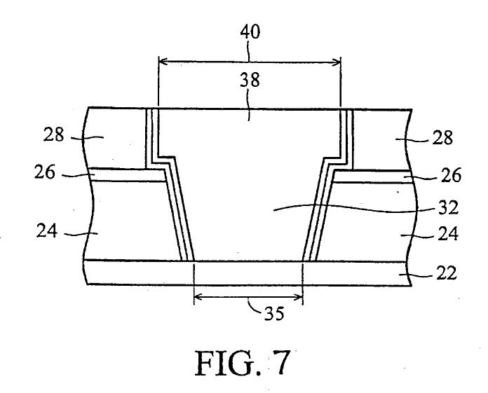

Via openings 30 extend through the lower dielectric layer 24, and trench openings 36 extend through the upper dielectric layer 28. Metal vias 32 fill the via openings 30, and a metal line 38 fills each trench opening 36. Each metal line 38 has a trench top width 40. Each via 32 has a via top width 34 and a via bottom width 35 (FIG. 7). According to the present invention, each via bottom width 35 is preferably less than about 0.25 μm. The ratio of the trench top width 40 to the via bottom width 35 is preferably about 1˜20.

A barrier layer 42, which is preferably tantalum (Ta) and has a thickness of greater than typically about 10 angstroms, coats each via opening 30 and trench opening 36. A seed layer 44, which is preferably copper and has a preferred thickness of greater than typically about 50 angstroms, is formed on top of the barrier layer 42. As shown in FIG. 5, multiple metal lines 38, each having one or multiple underlying vias 32, typically extend adjacent to each other on the substrate 22 and may extend in various directions to connect integrated circuit devices (not shown) to each other in the interconnect structure 20.

A dual damascene process for fabrication of the interconnect structure 20 typically begins with deposition of the lower dielectric layer 24 in a desired thickness which corresponds to the thickness for the vias 32 to be formed in the lower dielectric layer 24. Next, the etch stop layer 26, which is typically silicon nitride, silicon oxynitride, silicon carbide or combination thereof, is deposited on the lower dielectric layer 24. Subsequently, dielectric layer 28 is deposited on the etch stop layer 26.

Photolithography is then followed by dry etching to pattern the trench openings 36 in the upper dielectric layer 28 and the via openings 30 in the lower dielectric layer 24, under the trench openings 36. The trench etching process stops at the etch stop layer 26, while via openings 30 are etched through the etch stop layer into the lower dielectric layer 24. Next, barrier layer 42 is deposited on the sidewalls and the bottoms in the trench openings 36 and via openings 30 by an ionized PVD process. The seed layer 44 is then deposited on the barrier layer 42 using CVD.

The vias 32 and metal lines 38 are formed in the via openings 30 and trench openings 36, respectively, by electroplating with copper using electroplating techniques which may be carried out in a conventional electroplating apparatus (not shown). The electroplating solution may contain additives such as accelerators (which increase the electroplating rate) and suppressors (which decrease the electroplating rate) to achieve a desired metal electroplating rate. According to the present invention, the A/S (Accelerator/Suppressor) concentration ratio in the electroplating solution is less than about 10. Most preferably, the A/S concentration ratio is greater than about 3 and less than about 10. The metal is electroplated at a current density of preferably less than typically about 20 mA/cm². After the electroplating step, copper overburden (not shown) extending from the trench openings 36 is removed and the upper surfaces of the metal lines 38 are planarized using CMP.

In the interconnect structure 20, the ratio of the sum of the areas of all the trench metal lines 38 to the sum of the areas of all the metal vias 32 defines the trench/via pattern density ratio. The area of each trench metal line 38 is determined by multiplying the trench top width 40 of each trench metal line 38 by the length of the trench metal line 38. Similarly, the area of each via 32 is determined by multiplying the via top area of each via 32 by the number of the via 32. The sum of the areas obtained for the trench metal lines 38 and the sum of the areas obtained for the vias 32 are then used to determine the trench/via pattern density ratio. The lower the trench/via pattern density ratio, the higher the density of vias 32 in the interconnect structure 20 indicative of a structure similar to the “dense” type shown in FIG. 3(A). According to the present invention, the “dense” type interconnect structure 20 is advantageous since it has wider range for optimized electroplating. More specifically, a trench/via pattern density ratio of less than 300 is preferably, and a ratio of less than 100 is more preferably.

As shown in FIG. 6, the metal lines 38 in the interconnect structure 20 can be divided into square areas of decreasing size. The square areas may include, for example, an outer square area 46 having dimensions of 200 μm 200 μm; an outer middle square area 48 having dimensions of 100 μm×100 μm; an inner middle square area 50 having dimensions of 50 μm×50 μm; and an inner square area 52 having dimensions of 15 μm×15 μm. According to the present invention, the improvement in reducing void and contamination formation is significant for areas with the trench/via pattern density ratio calculated for the interconnect structure 20 based on all the trench metal lines 38 and vias 32 within the outer square area 52. It is believed that the improvement can also take effect in areas with larger size, such as the outer middle square area 48, the inner middle square area 50, or the inner square area 52. This is not only based on an assumption that a larger area is only a cumulation of smaller areas, but also that the possibility of void and contamination formation is higher in larger areas than in smaller areas. Thus an effective modification in smaller areas is deemed necessary in larger areas.

While the preferred embodiments of the invention have been described above, it will be recognized and understood that various modifications can be made in the invention and the appended claims are intended to cover all such modifications which may fall within the spirit and scope of the invention.

1. An interconnect structure comprising:
a substrate;
a low-k dielectric layer formed over said substrate; and
a plurality of trenches and vias having a trench/via pattern density ratio of less than about 300 formed in said dielectric layer.

2. The structure of claim 1 wherein each of said vias has a via bottom width of less than about 0.25 μm.

3. The structure of claim 1 wherein each of said vias has a via bottom width of less than about 0.20 μm.

4. The structure of claim 1 wherein each of said vias has a via bottom width of less than about 0.15 μm.

5. The structure of claim 1 wherein each of said vias has a via bottom width of less than about 0.10 μm.

6. The structure of claim 1 wherein said trench/via pattern density ratio is calculated in a square area of 200 μm×200 μm.

7. The structure of claim 1 wherein said trench/via pattern density ratio is calculated in a square area of 100 μm×100 μm.

8. The structure of claim 1 wherein said trench/via pattern density ratio is calculated in a square area of 50 μm×50 μm.

9. The structure of claim 1 wherein said trench/via pattern density ratio is calculated in a square area of 15 μm×15 μm.

10. The structure of claim 1 further comprising a barrier layer between said dielectric layer and said trenches and between said dielectric layer and said vias.

11. The structure of claim 10 wherein said barrier layer has a thickness of greater than about 10 angstroms.

12. The structure of claim 10 wherein said barrier layer comprises tantalum.

13. The structure of claim 1 further comprising a seed layer between said dielectric layer and said trenches and between said dielectric layer and said vias.

14. The structure of claim 13 wherein said seed layer has a thickness of greater than about 50 angstroms.

15. The structure of claim 13 wherein said seed layer comprises copper.

16. The structure of claim 1 wherein said low-k dielectric layer is formed by a low-k dielectric material selected from the group consisting of FSG, Black Diamond®, Blok®, Silk®, Coral® and DEMS.

17. The structure of claim 1 wherein said low-k dielectric layer is formed by a low-k dielectric material having a dielectric constant (k) of less than 3.9.

18. The structure of claim 1 wherein said low-k dielectric layer is formed by a low-k dielectric material having a dielectric constant (k) of less than 3.0.

19. An interconnect structure comprising:
a substrate;
a low-k dielectric layer provided over said substrate;
at least one trench formed in said low-k dielectric layer; and
at least one via formed inside said at least one trench;
said at least one trench and said at least one via having a trench top width/via bottom width ratio of between about 1 and about 20.

20. The structure of claim 19 wherein said trench top width/via bottom width ratio is not greater than about 10.

21. The structure of claim 19 wherein said trench top width/via bottom width ratio is not greater than about 5.

22. The structure of claim 19 wherein said at least one via has a via bottom width of less than about 0.25 μm.

23. The structure of claim 19 wherein said at least one via has a via bottom width of less than about 0.20 μm.

24. The structure of claim 19 wherein said at least one via has a via bottom width of less than about 0.15 μm.

25. The structure of claim 19 wherein said at least one via has a via bottom width of less than about 0.10 μm.

26. The structure of claim 19 further comprising a barrier layer between said dielectric layer and said trench and between said dielectric layer and said at least one via.

27. The structure of claim 26 wherein said barrier layer has a thickness of greater than about 10 angstroms.

28. The structure of claim 26 wherein said barrier layer comprises tantalum.

29. The structure of claim 19 further comprising a seed layer between said dielectric layer and asid trench and between said dielectric layer and said at least one vias.

30. The structure of claim 29 wherein said seed layer has a thickness of greater than about 50 angstroms.

31. The structure of claim 29 wherein said seed layer comprises copper.

32. The structure of claim 19 wherein said low-k dielectric layer is formed of a low-k dielectric material selected from the group consisting of FSG, Black Diamond®, Blok®, Silk®, Coral® and DEMS.

33. The structure of claim 19 wherein said low-k dielectric layer is formed of a low-k dielectric material having a dielectric constant less than 3.9.

34. The structure of claim 19 wherein said low-k dielectric layer is formed of a low-k dielectric material having a dielectric constant less than 3.0.

35. A method of fabricating a dual-damascene structure, comprising the steps of:
providing a substrate;
forming a dielectric layer having trench openings and via openings on said substrate, said via openings having a via bottom width of less than about 0.25 μm; and
forming metal lines and vias in said trench openings and said via openings, respectively, by electroplating a metal in said trench openings and said via openings, said metal lines and vias having a trench/via pattern density ratio of less than 300.

36. The method of claim 35 wherein said step of electroplating a metal in said trench openings and said via openings further comprises providing an electroplating solution comprising accelerators and suppressors and electroplating said metal in said trench openings and said via openings in said electroplating solution.

37. The method of claim 36 wherein said accelerators and suppressors are present in said electroplating solution in an accelerator/suppressor concentration ratio of less than about 10.

38. The method of claim 36 wherein said accelerators and suppressors are present in said electroplating solution in an accelerator/suppressor concentration ratio of greater than about 3.

39. The method of claim 35 wherein each of said vias has a via bottom width of less than about 0.20 μm.

40. The method of claim 35 wherein each of said vias has a via bottom width of less than about 0.15 μm.

41. The method of claim 35 wherein each of said vias has a via bottom width of less than about 0.10 μm.

42. The method of claim 35 further comprising the step of providing a barrier layer in said trench opening and said via openings before said electroplating step.

43. The method of claim 42 wherein said barrier layer has a thickness of greater than about 10 angstroms.

44. The method of claim 42 wherein said barrier layer comprises tantalum.

45. The method of claim 35 further comprising the step of providing a seed layer in said trench openings and said via openings before said electroplating step.

46. The method of claim 45 wherein said seed layer has a thickness of greater than about 50 angstroms.

47. The method of claim 43 wherein said seed layer comprises copper.
